(19) United States
(12) Patent Application Publication
(10) Pub. No.: US 2025/0359072 A1
(43) Pub. Date: Nov. 20, 2025

(54) PHASE-CHANGE DEVICE STRUCTURE

(71) Applicant: Taiwan Semiconductor Manufacturing Company, Ltd., Hsinchu (TW)

(72) Inventors: Fu-Ting Sung, Taoyuan County (TW); Tsung-Hsueh Yang, Taichung City (TW); Chang-Ming Wu, New Taipei City (TW); Chang-Chih Huang, Taichung (TW); Yu-Wen Wang, Taichung City (TW); Kuo-Chyuan Tzeng, Hsin-Chu County (TW)

(21) Appl. No.: 19/284,950

(22) Filed: Jul. 30, 2025

Related U.S. Application Data
(62) Division of application No. 18/150,863, filed on Jan. 6, 2023.
(60) Provisional application No. 63/398,023, filed on Aug. 15, 2022.
(60) Provisional application No. 63/410,069, filed on Sep. 26, 2022.

(51) Int. Cl. H10B 63/10; H10N 70/00

(52) U.S. Cl. CPC H10B 63/10; H10N 70/021; H10N 70/063; H10N 70/841; H10N 70/8828

(57) ABSTRACT

Device structures and methods for forming the same are provided. A device structure according to the present disclosure includes a first electrode and a second electrode disposed over an etch stop layer (ESL), a first dielectric layer disposed between the first electrode and the second electrode, a phase-change material layer disposed over the first electrode, the first dielectric layer and the second electrode, an insulator layer disposed over the phase-change material layer, a metal feature disposed over the insulator layer, and a second dielectric layer disposed over the insulator layer, the first electrode, the second electrode, and the metal feature.

### PRIORITY DATA

This application is a divisional application of U.S. patent application Ser. No. 18/150,863, filed Jan. 6, 2023, which claims priority to U.S. Provisional Patent Application Ser. No. 63/410,069 filed on Sep. 26, 2022, and U.S. Provisional Patent Application Ser. No. 63/398,023 filed on Aug. 15, 2022, each of which is hereby incorporated by reference in its entirety.

### BACKGROUND

In recent years, phase-change memory (PCM) devices have emerged as promising alternative nonvolatile memory (NVM) devices. The core of a PCM is a phase-change element that exhibits a switching behavior between a high resistance amorphous state and a low resistance crystalline state. Besides serving as a memory device, a PCM structure may be configured to serve as a switch. While existing PCM structures and processes for forming the same are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a flow chart of a method 100 of forming a PCM structure, according to various aspects of the present disclosure.

FIGS. 2-11 illustrate fragmentary cross-sectional views of a workpiece undergoing various operations of the method 100 in FIG. 1, according to various aspects of the present disclosure.

FIGS. 12 and 13 are schematic top views of the PCM structure illustrated in FIG. 11, according to various aspects of the present disclosure.

FIG. 14 illustrates a flow chart of a method 300 of forming a PCM structure, according to various aspects of the present disclosure.

FIGS. 15-21 illustrate fragmentary cross-sectional views of a workpiece undergoing various operations of the method 300 in FIG. 14, according to various aspects of the present disclosure.

FIG. 22 illustrates a flow chart of a method 400 of forming a PCM structure, according to various aspects of the present disclosure.

FIGS. 23-30 illustrate fragmentary cross-sectional views of a workpiece undergoing various operations of the method 400 in FIG. 22, according to various aspects of the present disclosure.

FIGS. 31-33 illustrate alternative PMC structures formed using the methods in FIGS. 1, 14 and 22, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure is generally related to phase-change memory (PCM) structure and methods of forming the same. A phase-change memory is a type of nonvolatile memory that includes a phase-change material, such as chalcogenide semiconductors in some embodiments. At different temperatures, the phase-change material can switch between a low-resistance crystalline state and a high-resistance amorphous state. In some existing structures, a resistive heating element is used to heat up the phase-change material to switch between the two states The phase-change material is stable at certain temperature ranges in both crystalline and amorphous states and can be switched back and forth between the two states by heat excitations. Because the resistivity ratios of the phase-change material in the amorphous and crystalline states are typically greater than 1000, the PCM structure may also be used a switch. A PCM structure has several operating and engineering advantages, including high speed, low power, non-volatility, high density, ready process integration, and low cost.

In some existing PCM structures, a heating element is disposed below a phase-change element. While these existing PCM structures are fully functional, it may be challenging to maintain a low off-state capacitance (Coff) or to prevent undesirable damages to the phase-change material layer. The present disclosure provides a PCM structure where a phase-change element is disposed over the electrodes and a heating element is disposed over the phase-change element. The heating element is spaced apart from the phase-change element by an insulator layer. The PCM structure of the present disclosure provides a low off-state capacitance (Coff) due to an increased distance between the electrodes and the heating element. The present disclosure also provides methods to form the PCM structure. The methods forming the PCM structures create a low risk of damaging the phase-change element during the fabrication steps.

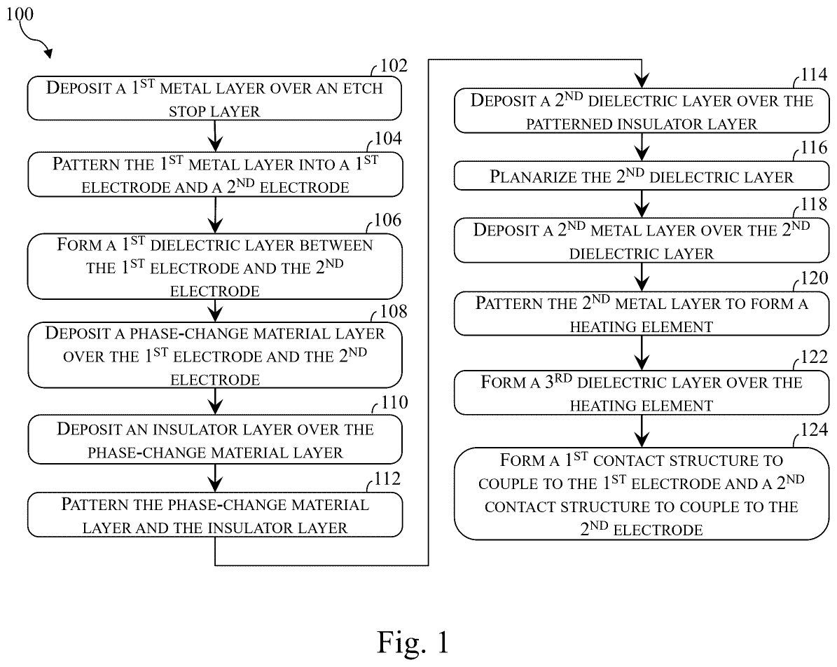

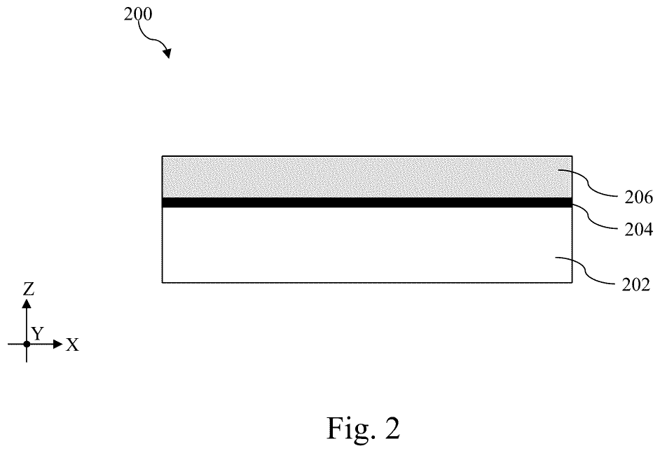

The various aspects of the present disclosure will now be described in more detail with reference to the figures. FIGS. 1, 13 and 21 are flowcharts of methods 100, 300 and 400 for fabricating a semiconductor device according to various aspects of the present disclosure. Methods 100, 300 and 400 are merely examples and not intended to limit the present disclosure to what is explicitly illustrated in methods 100, 300 and 400. Additional steps can be provided before, during, and after method 100, 300 or 400, and some of the steps described can be moved, replaced, or eliminated for additional embodiments. Not all steps are described herein in detail for reasons of simplicity. Methods 100, 300 and 400 will be described below in conjunction with the fragmentary cross-sectional views of a workpiece 200 shown in FIGS. 2-12, 14-20, and 22-29. Because a PCM structure will be formed from the workpiece 200, the workpiece 200 may be referred to as a PCM structure 200 as the context requires. Additionally, throughout the present disclosure, like reference numerals denote like features, unless otherwise described.

Referring to FIGS. 1 and 2, method 100 includes a block 102 where a first metal layer 206 is deposited over an etch stop layer (ESL) 204 that includes a dielectric material. The ESL 204 may include silicon nitride, silicon oxycarbide, or silicon carbide. In the depicted embodiments, the ESL 204 is disposed over an intermetal dielectric (IMD) layer 202. The IMD layer 202 may include silicon oxide. In some embodiments, the IMD layer 202 may include a porous organosilicate thin film such as SiOCH, tetraethylorthosilicate (TEOS) oxide, un-doped silicate glass, doped silicon oxide such as borophosphosilicate glass (BPSG), fused silica glass (FSG), phosphosilicate glass (PSG), fluorine-doped silicon dioxide, carbon-doped silicon dioxide, porous silicon dioxide, porous carbon-doped silicon dioxide, or a combination thereof. In at least some embodiments, the PCM structure fabricated using method 100 is disposed within an interconnect structure, which is considered a back-end-of-line (BEOL) structure. In these embodiments, the PCM structure may be used as a solid state switch to switch among different communication frequencies. As an example, the PCM structure may be used to switch among different fifth-generation (5G) frequencies. Such an interconnect structure may include eight (8) to nineteen (19) metal layers. Each of the metal layer includes a plurality of vertically extending contact vias and horizontally extending metal lines. The contact vias and metal lines for each metal layer are embedded in an ESL similar to the ESL 204 and an IMD layer similar to the IMD layer 202. The ESL 204 and the IMD layer 202 shown in FIG. 2 may be part of an interconnect structure. The first metal layer 206 may include tantalum (Ta), titanium (Ti), hafnium (Hf), ruthenium (Ru), platinum (Pt), iridium (Ir), molybdenum (Mo), tungsten (W), a combination thereof, or a nitride compound thereof. At block 102, the first metal layer 206 may be deposited using physical vapor deposition (PVD) or a suitable method. In one embodiment, the first metal layer 206 is formed of tungsten (W). The ESL 204 and the IMD layer 202 may be formed over a semiconductor wafer. The ESL 204, the IMD 202, and/or the semiconductor wafer may be regarded as a substrate.

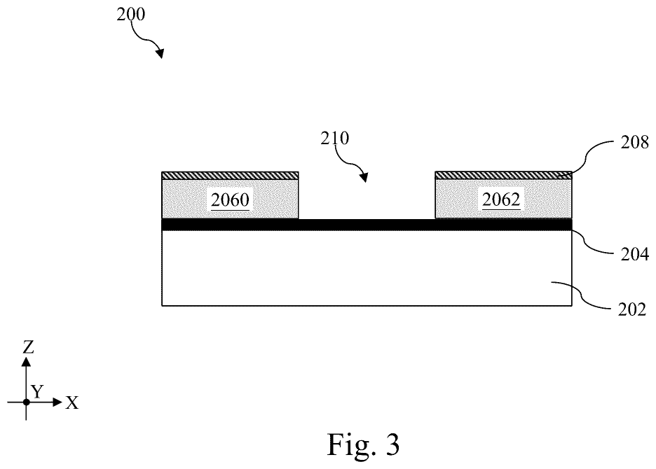

Referring to FIGS. 1 and 3, method 100 includes a block 104 where the first metal layer 206 is patterned into a first electrode 2060 and a second electrode 2062. In some embodiments, the patterning at block 104 includes lithography and etching processes. In an example process, a first mask layer 208 is deposited over the first metal layer 206. The first mask layer 208 may include a photoresist. The first mask layer 208 is then patterned using photolithography techniques to form a patterned first mask layer 208 that includes a first opening 210. The patterned first mask layer 208 is then applied as an etch mask to etch the first metal layer 206 to form the first electrode 2060 and the second electrode 2062 that are spaced apart from one another along the X direction. A suitable etch process may be an anisotropic dry etch process that uses an inert gas (e.g., Ar, He), a fluorine-containing gas (e.g., SF₆, CHF₃), a chlorine-containing gas (e.g., Cl₂, BCl₃), nitrogen (N₂), oxygen (O₂), other suitable gases and/or plasmas, and/or combinations thereof. As the first electrode 2060 and the second electrode 2062 of the present disclosure are sufficiently electrically conductive for radio frequency applications, they may also be referred to as the first RF electrode 2060 and the second RF electrode 2062.

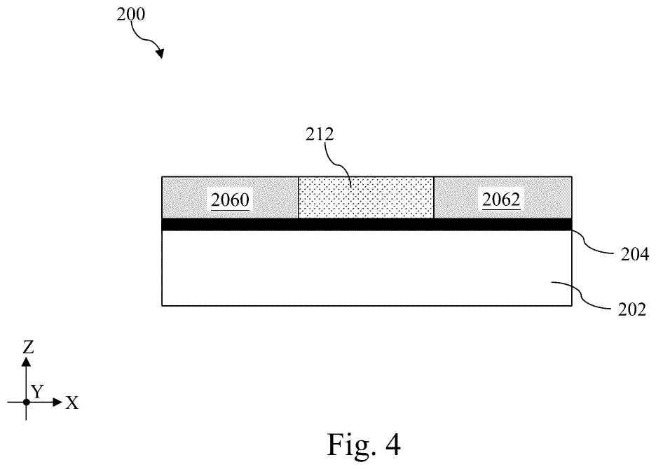

Referring to FIGS. 1 and 4, method 100 includes a block 106 where a first dielectric layer 212 is formed between the first electrode 2060 and the second electrode 2062. In some embodiments, the first dielectric layer 212 has a composition similar to that of the IMD layer 202. The first dielectric layer 212 may be deposited using flowable chemical vapor deposition (FCVD), CVD, or spin-on coating. After the first dielectric layer 212 is deposited over the ESL layer 204 exposed between the first electrode 2060 and the second electrode 2062, the first dielectric layer 212 is planarized to expose top surfaces of the first electrode 2060 and the second electrode 2062. In other words, the planarization is performed until top surfaces of the first dielectric layer 212, the first electrode 2060 and the second electrode 2062 are coplanar, as shown in FIG. 4. The planarization at block 106 may include a chemical mechanical polishing (CMP) process.

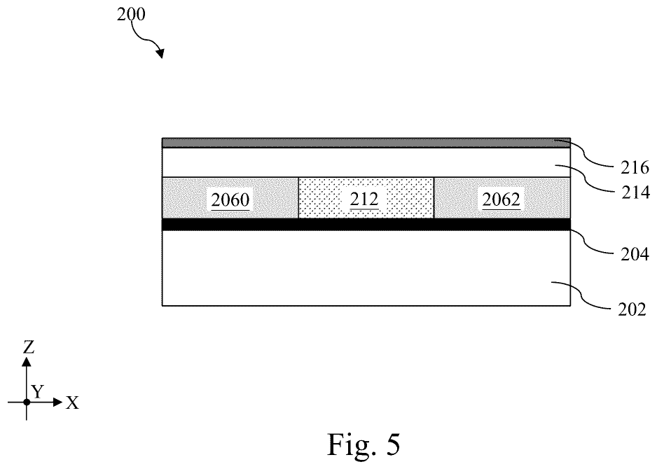

Referring to FIGS. 1 and 5, method 100 includes a block 108 where a phase-change material layer 214 is deposited over the first electrode 2060 and the second electrode 2062. In some embodiments, the phase-change material layer 214 may include chalcogenide materials. Generally, chalcogenide materials refer to chemical compounds that include at least one chalcogen ion from column VI of the periodic table. Chalcogenide materials may include sulphides, selenides, and tellurides. In some embodiments, the phase-change material layer 214 includes germanium (Ge), Tellurium (Te), and Antimony (Sb). In some instances, the phase-change material layer 214 includes germanium antimony tellurium (GeSbTe), silver indium antimony tellurium (AgInSbTe), or germanium tellurium (GeTe). To improve its performance, the phase-change material layer 214 may also be doped with various dopants, such as silicon (Si) or nitrogen (N). The phase-change material layer 214 may be deposited using PVD. In some implementations, the phase-change material layer 214 may be deposited using co-sputtering from multiple targets or sputtering from a composite targets. In some instances, the composite target may have a composition similar to that of the phase-change material layer 214.

Referring to FIGS. 1 and 5, method 100 includes a block 110 where an insulator layer 216 is deposited over the phase-change material layer 214. In some embodiments, the insulator layer 216 includes silicon nitride, silicon oxycarbide, or silicon carbide. The insulator layer 216 may be deposited using CVD or a suitable technique. The insulator layer 216 serves multiple purposes. In one aspect, the insulator layer 216 serves as a thermal barrier to prevent abrupt heating profile that may damage the phase-change properties of the phase-change material layer 214 For example, if the to-be-formed heating element is in direct contact with the phase-change material layer 214, heat generated by the heating element may permanently transform a portion of the phase-change material layer 214 to the crystalline state. In another aspect, the insulator layer 216 serves a protective layer to prevent damages done to the phase-change material layer 214 during the patterning of the heating element. In this aspect, the insulator layer 216 cannot be too thick or it will prevent the heating element from efficiently heating up the phase-change material layer 214. Based on these considerations, the insulator layer 216 may have a thickness between about 300 Å and about 1500 Å. The insulator layer 216 may not perform both functions well when it is thinner than 300 Å or thicker than 1500 Å.

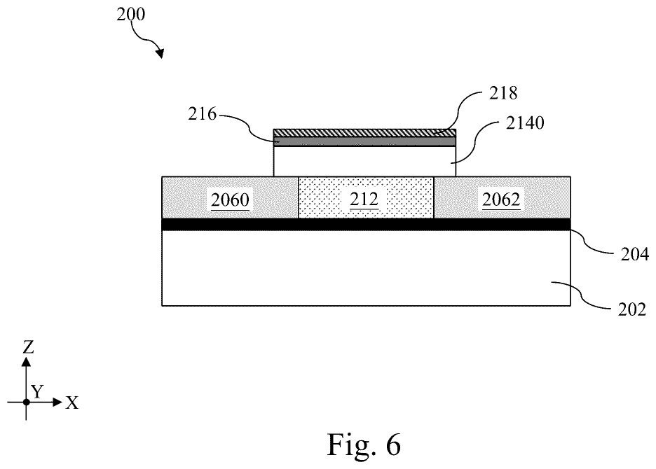

Referring to FIGS. 1 and 6, method 100 includes a block 112 where the phase-change material layer 214 and the insulator layer 216 are patterned. At block 112, the deposited phase-change material layer 214 and the insulator layer 216 are patterned together. In an example process depicted in FIG. 6, a second mask layer 218 is patterned to serve as an etch mask as the phase-change material layer 214 and the insulator layer 216 are etched to form a phase-change element 2140. The second mask layer 218 may include a photoresist. As shown in FIG. 6, the phase-change material layer 214 is patterned such that the phase-change element 2140 extends over or spans over the first electrode 2060, the first dielectric layer 212, and the second electrode 2062. In other words, along the vertical direction (i.e., Z direction), the phase-change element 2140 overlaps with the first electrode 2060, the second electrode 2062, and the first dielectric layer 212. The phase-change element 2140 is in direct contact with the first electrode 2060 and the second electrode 2062.

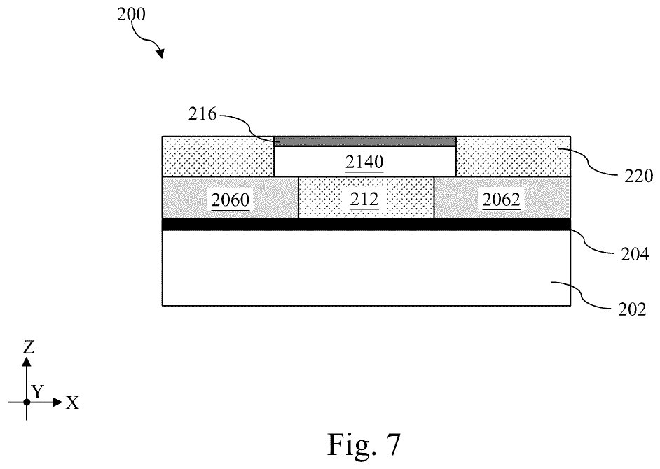

Referring to FIGS. 1 and 7, method 100 includes a block 114 where a second dielectric layer 220 is deposited over the patterned insulator layer 216. After the phase-change element 2140 is formed, a second dielectric layer 220 is deposited over the first electrode 2060, the insulator layer 216 and the second electrode 2062. In some embodiments, the second dielectric layer 220 may have a composition similar to that of the IMD layer 202. The second dielectric layer 220 may be deposited using FCVD, CVD, or spin-on coating.

Referring to FIGS. 1 and 7, method 100 includes a block 116 where the second dielectric layer 220 is planarized. After the second dielectric layer 220 is deposited over the first electrode 2060, the insulator layer 216 and the second electrode 2062, the second dielectric layer 220 and the patterned second mask layer 218 are planarized to expose top surfaces of the insulator layer 216 and the second dielectric layer 220. In other words, the planarization is performed until the patterned second mask layer 218 is completely removed. The planarization at block 116 may include a chemical mechanical polishing (CMP) process.

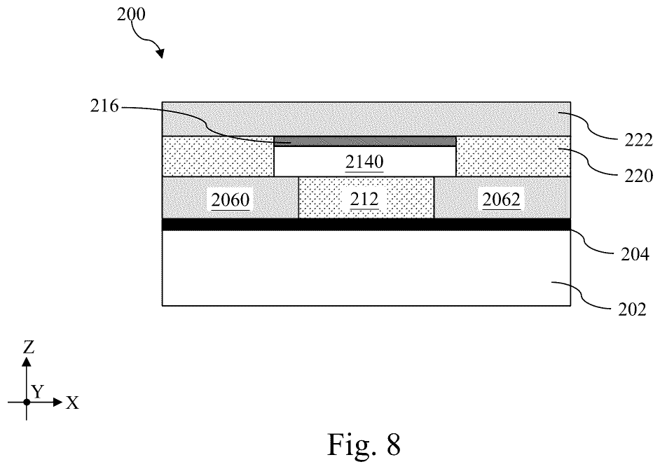

Referring to FIGS. 1 and 8, method 100 includes a block 118 where a second metal layer 222 is deposited over the second dielectric layer 220. Like the first metal layer 206, the second metal layer 222 may include tantalum (Ta), titanium (Ti), hafnium (Hf), ruthenium (Ru), platinum (Pt), iridium (Ir), molybdenum (Mo), tungsten (W), a combination thereof, or a nitride compound thereof. In one embodiment, the second metal layer 222 is formed of tungsten (W). In this embodiment, tungsten has a low resistance to reduce energy consumption. At block 118, the second metal layer 222 may be deposited over the second dielectric layer 220 and the patterned insulator layer 216 using PVD or a suitable method.

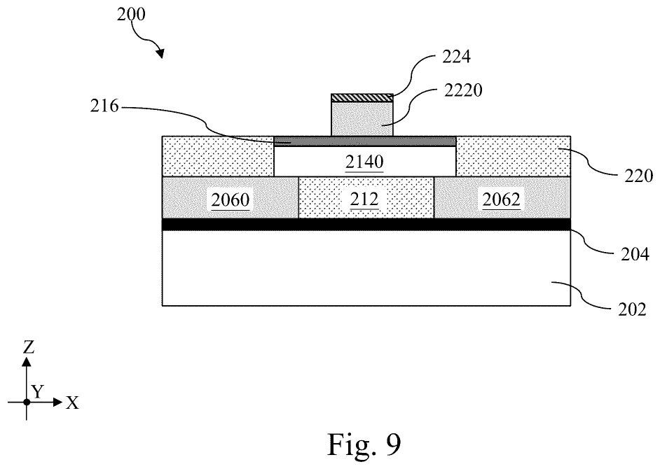

Referring to FIGS. 1 and 9, method 100 includes a block 120 where the second metal layer 222 is patterned to form a heating element 2220. In some embodiments, the patterning at block 120 includes lithography and etching processes. In an example process, a third mask layer 224 is deposited over the second metal layer 222. The third mask layer 224 may include a photoresist. The third mask layer 224 is then patterned using photolithography techniques to form a patterned third mask layer 224. As shown in FIG. 9, the patterned third mask layer 224 is narrower than the patterned insulator layer 216 along the X direction. In the depicted embodiment, when viewed along the Y direction, the patterned third mask layer 224 is disposed directly over the patterned insulator layer 216, the heating element 2220, and the first dielectric layer 212 between the first electrode 2060 and the second electrode 2062. The patterned third mask layer 224 is then applied as an etch mask to etch the second metal layer 222 to form the heating element 2220. A suitable etch process may be an anisotropic dry etch process that uses an inert gas (e.g., Ar, He), a fluorine-containing gas (e.g., SF₆, CHF₃), a chlorine-containing gas (e.g., Cl₂, BCl₃), nitrogen (N₂), oxygen (O₂), other suitable gases and/or plasmas, and/or combinations thereof. Like the patterned third mask layer 224, when viewed along the Y direction, the heating element 2220 is disposed directly over the patterned insulator layer 216, the phase-change element 2140, and the first dielectric layer 212 between the first electrode 2060 and the second electrode 2062.

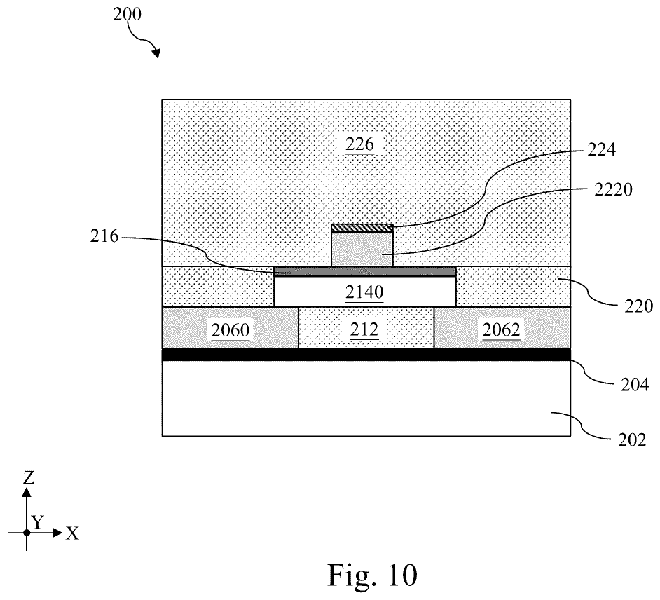

Referring to FIGS. 1 and 10, method 100 includes a block 122 where a third dielectric layer 226 is deposited over heating element 2220. In some embodiments, the third dielectric layer 226 may include silicon oxide. In some embodiments, the third dielectric layer 226 may include a porous organosilicate thin film such as SiOCH, tetraethylorthosilicate (TEOS) oxide, un-doped silicate glass, doped silicon oxide such as borophosphosilicate glass (BPSG), fused silica glass (FSG), phosphosilicate glass (PSG), fluorine-doped silicon dioxide, carbon-doped silicon dioxide, porous silicon dioxide, porous carbon-doped silicon dioxide, or a combination thereof. In at least some embodiments of the present disclosure, the first dielectric layer 212, the second dielectric layer 220 and the third dielectric layer 226 may have the same composition, such as silicon oxide. As shown in FIG. 10, because the third dielectric layer 226 is blanketly deposited, the third dielectric layer 226 is deposited over the second dielectric layer 220, the patterned insulator layer 216, sidewalls of the heating element 2220, and the exposed surfaces of the third mask layer 224. It is noted that the third mask layer 224 on the heating element 2220 is not removed before the deposition of the third dielectric layer 226. As a result, the third mask layer 224 is disposed between a top surface of the heating element 2220 and the third dielectric layer 226. In some instances, a composition of the third mask layer 224 may be different from or identical to the third dielectric layer 226. When the composition of the third mask layer 224 is different from that of the third dielectric layer 226, the third mask layer 224 may serve as an etch stop layer when forming contact structures to the heating element 2220. For example, the third mask layer 224 may include silicon nitride while the third dielectric layer 226 includes silicon oxide.

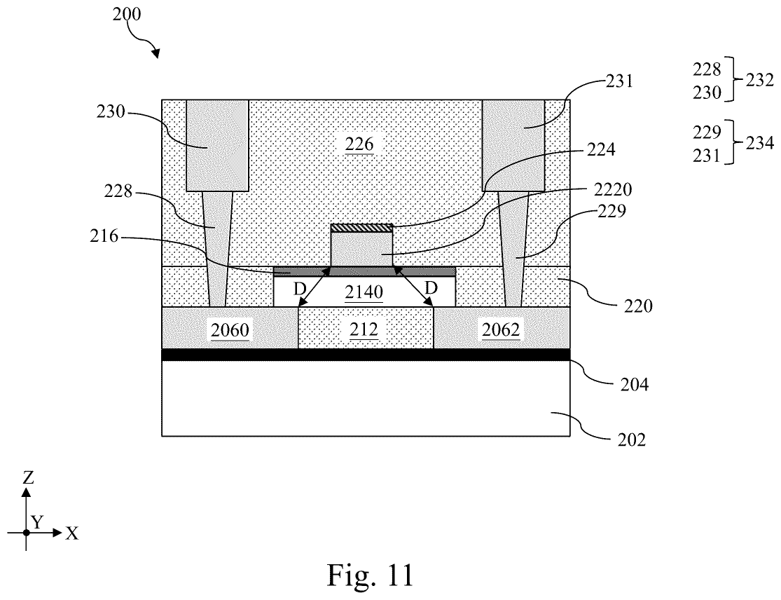

Referring to FIGS. 1 and 11, method 100 includes a block 124 where a first contact structure 232 is formed to couple to the first electrode 2060 and a second contact structure 234 is formed to couple to the second electrode 2062. In the depicted embodiments, the first contact structure 232 includes a first via 228 and a first metal line 230 disposed on the first via 228 and the second contact structure 234 includes a second via 229 and a second metal line 231 disposed on the second via 229. The first via 228, the second via 229, the first metal line 230, and the second metal line 231 may include aluminum (Al), copper (Cu), cobalt (Co), or nickel (Ni). In one embodiment, they all include copper (Cu). In an example process, both the first contact structure 232 and the second contact structure 234 are formed using a dual damascene process. While not explicitly shown, the first contact structure 232 and the second contact structure 234 may include a barrier layer to interface the third dielectric layer 226 or the second dielectric layer 220. The barrier layer may include titanium nitride or tantalum nitride and function to reduce electromigration.

In the embodiments represented in FIG. 11, the first electrode 2060 and the second electrode 2062 are disposed below the phase-change element 2140 and the heating element 2220 is disposed above the phase-change element 2140. In other words, the electrodes and the heating element 2220 are disposed along opposing sides of the phase-change element 2140. The first electrode 2060 and the second electrode 2062 are disposed below and in contact with a bottom surface of the phase-change element 2140 and the heating element 2220 is disposed adjacent a top surface of the phase-change element 2140. The bottom surface is opposing the top surface. Because of this arrangement, a distance D between the heating element 2220 and the electrodes are increased, if not maximized, to reduce off-state capacitance (Coff) of the PCM structure 200. In some instances, the distance D may be between about 300 nm and about 5000 nm. Figures of merit (FOMs) are often used to assess performance of a radio frequency switch. FOM may be mathematically represented as 1/(2π·Coff·Ron), wherein Ron refers to the on-state resistance. It can be seen that the off-state capacitance (Coff) is inversely related to the FOM of the to-be-formed PCM structure. Ron is also inversely related to the FOM.

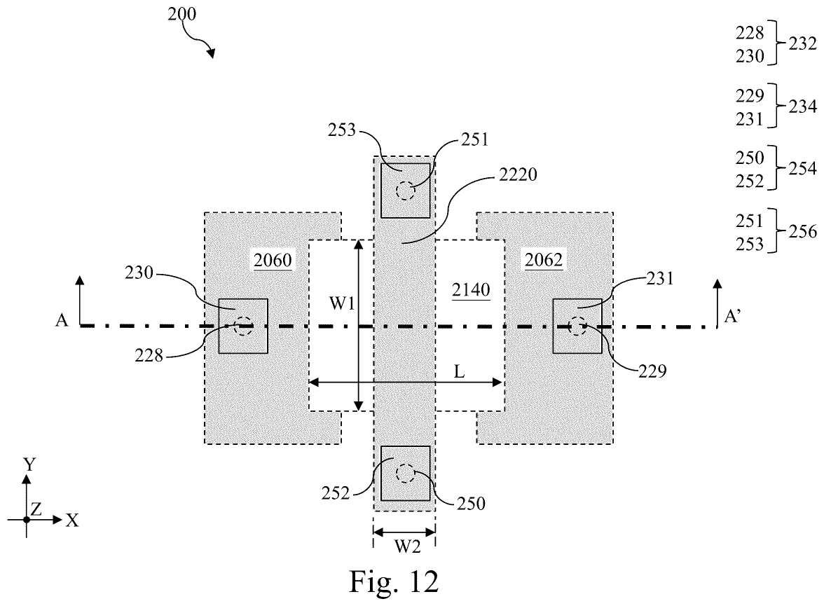

Reference is now made to FIG. 12, which is a top view of the PCM structure 200 shown in FIG. 11. In fact, the fragmentary cross-sectional view shown in FIG. 11 depicts structures along line A-A′ shown in FIG. 12. It is noted that, for simplicity of illustration, FIG. 12 does not include illustration of every single layer. For example, illustrations of the first dielectric layer 212, the second dielectric layer 220 and the third dielectric layer 226 are omitted from FIG. 12. In some embodiments represented in FIG. 12, each of the first electrode 2060 and the second electrode 2062 extends lengthwise along the Y direction. The phase-change element 2140 vertically overlap a portion of the first electrode 2060 and a portion of the second electrode 2062. To ensure that the phase-change element 2140 land on the first electrode 2060 and the second electrode 2062, the Y direction dimension of the phase-change element 2140 is smaller than the Y direction dimension of the first electrode 2060 or the second electrode 2062. As shown in FIG. 12, the heating element 2220 is elongated along the Y direction and spans across the phase-change element 2140. A third contact structure 254 and a fourth contact structure 256 vertically extend through the third dielectric layer 226 (shown in FIG. 11) to contact two terminal ends of the heating element 2220. Like the first contact structure 232 and the second contact structure 234, the third contact structure 254 includes a third via 250 and a third metal line 252 disposed on the third via 250. The fourth contact structure 256 includes a fourth via 251 and a fourth metal line 253 disposed on the fourth via 251.

In FIG. 12, the landing area of the first contact structure 232 on the first electrode 2060 and the landing area of the second contact structure 234 on the second electrode 2062 are pushed apart along the X direction within a suitable process window to reduce parasitic capacitance. Similarly, the landing areas of the third contact structure 254 and the fourth contact structure 256 on the heating element 2220 are pushed apart along the Y direction within a suitable process window to reduce parasitic capacitance. For avoidance of doubts, each of the third via 250 and the fourth via 251 also extend through the third mask layer 224 (shown in FIG. 11) to form electrical communication with the heating element 2220. When a current pass through the heating element 2220 by way of the third contact structure 254 and the fourth contact structure 256, the resistance in the heating element 2220 generates joule heating to heat up the phase-change element 2140. To reduce the off-state capacitance (Coff), a vertical projection of the heating element 2220 does not overlap with vertical projections of the first electrode 2060 and the second electrode 2062.

In the embodiments shown in FIG. 12, a length of the heating element 2220 along the Y direction is greater than a length of the first electrode 2060 or the second electrode 2062 along the Y direction such that the third contact structure 254 and the fourth contact structure 256 do not vertically overlap with the phase-change element 2140. Along the on-state current flow direction (X direction), the phase-change element 2140 has a length L. Perpendicular to the on-state current flow direction (Y direction), the phase-change element 2140 has a first conduction width W1. The heating element 2220 has a second conduction width W2 along the X direction, which is perpendicular to the heating current flow direction between the third via 250 and the fourth via 251. In some embodiments, the first conduction width W1 is greater than the second conduction width W2 for at least two reasons. First, the first conduction width W1 is inversely related to the on-state resistance (Ron). A greater first conduction width W1 helps reduces Ron and boost FOM of the resulting switch (i.e., PCM structure). Second, the heating element 2220, which is formed a metal, is more conductive than the phase-change element 2140 in its on-state. In some embodiments, a ratio of the first conduction width W1 to the second conduction width W2 may be between about 2 and about 5. To reduce energy consumption of the heating element 2220, the second conduction width W2 is made small and only spans over a middle portion of the phase-change element 2140. In some embodiments, a ratio of the length L of the phase-change element 2140 to the second conduction width W2 is between about 2 and about 6.

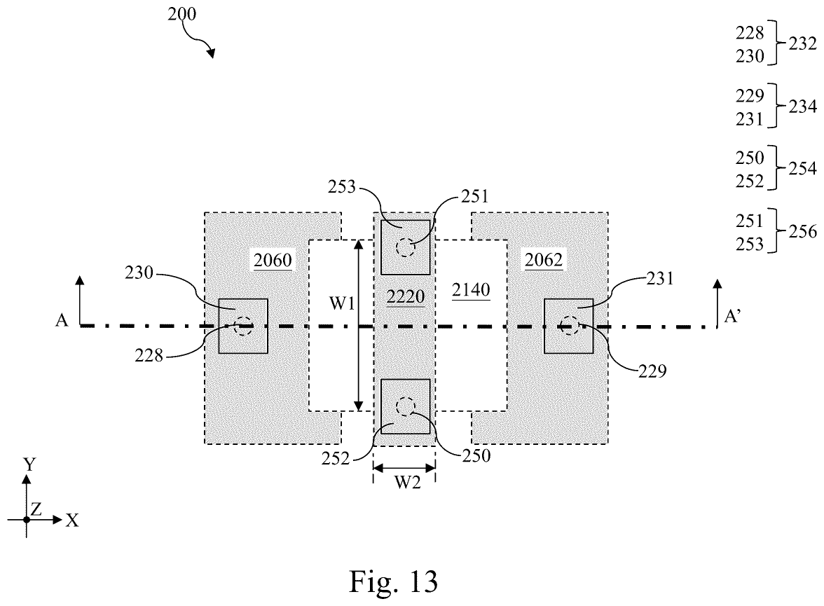

FIG. 13 provides a top view of an alternative embodiment of the PCM structure 200 shown in FIG. 11. Different from the PCM structure 200 shown in FIG. 12, the Y direction dimension of the heating element 2220 is equal or even smaller than the Y direction dimensions of the first electrode 2060 and the second electrode 2062. The smaller Y direction dimension of the heating element 2220 helps reduce the footprint of the PCM structure 200. The smaller footprint is helpful when more PCM structures 200 are needed.

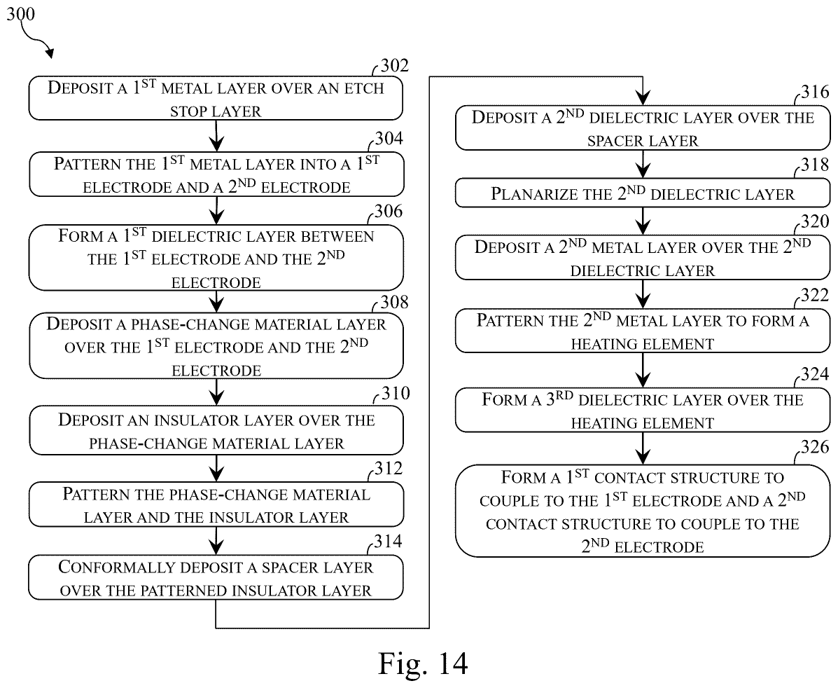

FIG. 14 illustrates a method 300. While method 300 and method 100 share several similar steps, method 300 at least further includes operations to form a spacer layer to isolate sidewalls of the phase-change element 2140 and top surfaces of the first electrode 2060 and the second electrode 2062 from the second dielectric layer 220.

Referring to FIGS. 14 and 2, method 300 includes a block 302 where a first metal layer 206 is deposited over an etch stop layer (ESL) 204. Operations at block 302 are substantially similar to those at block 102. For that reason, detailed description of operations at block 302 is omitted for brevity.

Referring to FIGS. 14 and 3, method 300 includes a block 304 where the first metal layer 206 is patterned into a first electrode 2060 and a second electrode 2062. Operations at block 304 are substantially similar to those at block 104. For that reason, detailed description of operations at block 304 is omitted for brevity.

Referring to FIGS. 14 and 4, method 300 includes a block 306 where a first dielectric layer 212 is formed between the first electrode 2060 and the second electrode 2062. Operations at block 306 are substantially similar to those at block 106. For that reason, detailed description of operations at block 306 is omitted for brevity.

Referring to FIGS. 14 and 5, method 300 includes a block 308 where a phase-change material layer 214 is deposited over the first electrode 2060 and the second electrode 2062. Operations at block 308 are substantially similar to those at block 108. For that reason, detailed description of operations at block 308 is omitted for brevity.

Referring to FIGS. 14 and 5, method 300 includes a block 310 where an insulator layer 216 is deposited over the phase-change material layer 214. Operations at block 310 are substantially similar to those at block 110. For that reason, detailed description of operations at block 310 is omitted for brevity.

Referring to FIGS. 14 and 6, method 300 includes a block 312 where the phase-change material layer 214 and the insulator layer 216 are patterned. Operations at block 312 are substantially similar to those at block 112. For that reason, detailed description of operations at block 312 is omitted for brevity.

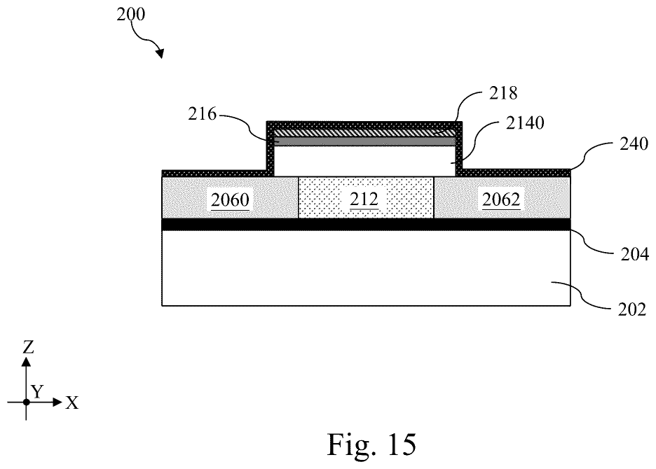

Referring to FIGS. 14 and 15, method 300 includes a block 314 where a spacer layer 240 is conformally deposited over the patterned second mask layer 218 and the patterned insulator layer 216. In some embodiments, the spacer layer 240 may include silicon nitride, silicon oxynitride, or silicon carbide. The spacer layer 240 may be deposited using CVD or a suitable method. As shown in FIG. 15, at block 314, the spacer layer 240 may be deposited along the top surface of the first electrode 2060, sidewalls of the phase-change element 2140, sidewalls of the insulator layer 216, sidewalls of the second mask layer 218, the top surface of the second mask layer 218, and the top surface of the second electrode 2062.

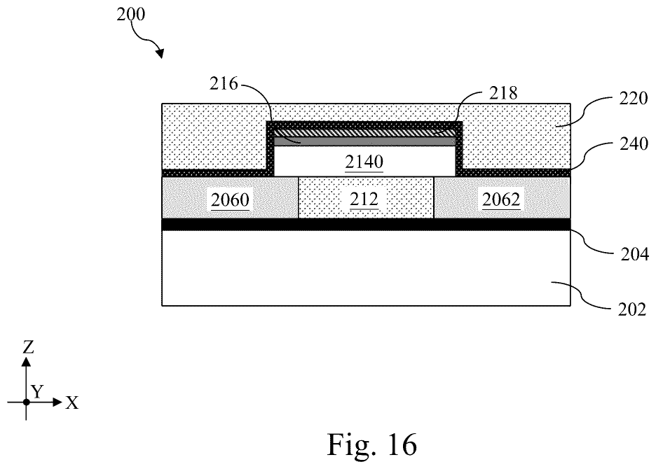

Referring to FIGS. 14 and 16, method 300 includes a block 316 where a second dielectric layer 220 is deposited over the spacer layer 240. Operations at block 316 are substantially similar to those at block 114 except that the second dielectric layer 220 is deposited over the spacer layer 240 at block 316. For that reason, detailed description of operations at block 316 is omitted for brevity.

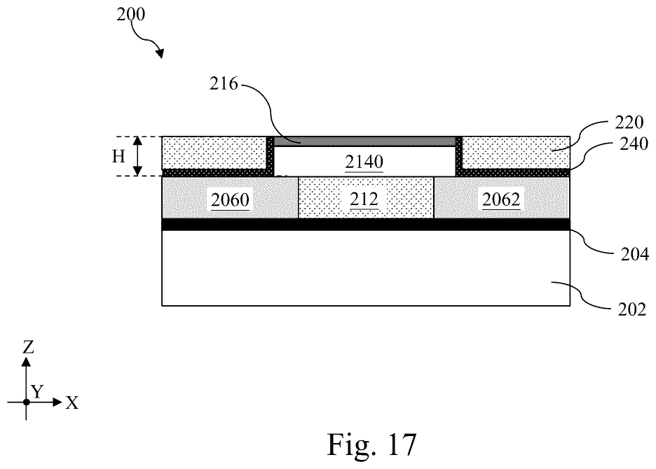

Referring to FIGS. 14 and 17, method 300 includes a block 318 where the second dielectric layer 220 is planarized. Operations at block 318 are substantially similar to those at block 116 except that the planarization at block 318 also planarizes the spacer layer 240 to expose the patterned insulator layer 216. For that reason, detailed description of operations at block 318 is omitted for brevity. In some embodiments illustrated in FIG. 17, after the planarization at block 318, the spacer layer 240 may have a height H between about 500 Å and about 2500 Å.

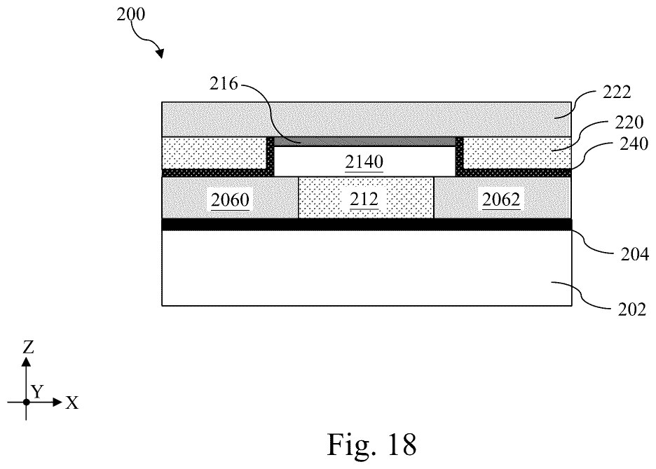

Referring to FIGS. 14 and 18, method 300 includes a block 320 where a second metal layer 222 is deposited over the second dielectric layer 220. Operations at block 320 are substantially similar to those at block 118 except that the second metal layer 222 is also deposited on top surfaces of the spacer layer 240. For that reason, detailed description of operations at block 320 is omitted for brevity.

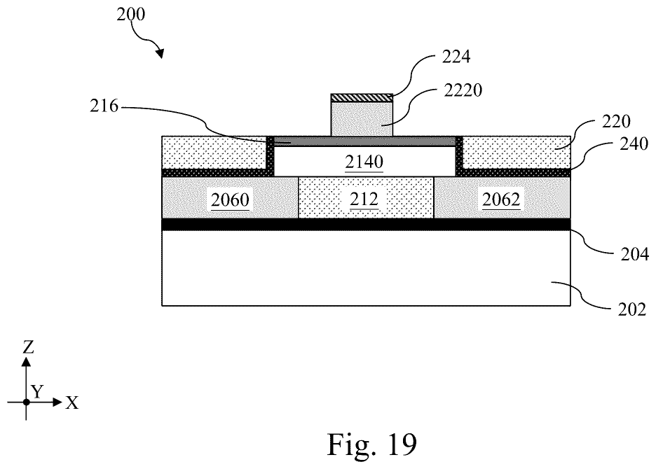

Referring to FIGS. 14 and 19, method 300 includes a block 322 where the second metal layer 222 is patterned to form a heating element 2220. Operations at block 322 are substantially similar to those at block 120. For that reason, detailed description of operations at block 322 is omitted for brevity.

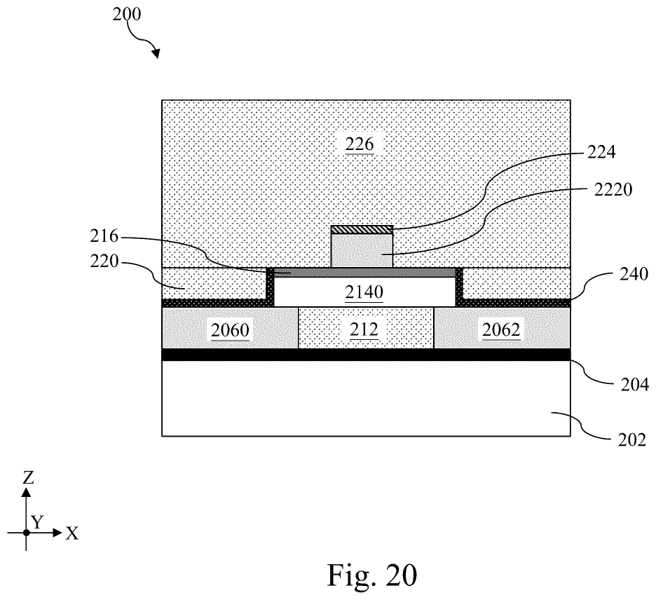

Referring to FIGS. 14 and 20, method 300 includes a block 324 where a third dielectric layer 226 is deposited over heating element 2220. Operations at block 324 are substantially similar to those at block 122 except that the third dielectric layer 226 is also deposited on top surfaces of the spacer layer 240. For that reason, detailed description of operations at block 324 is omitted for brevity.

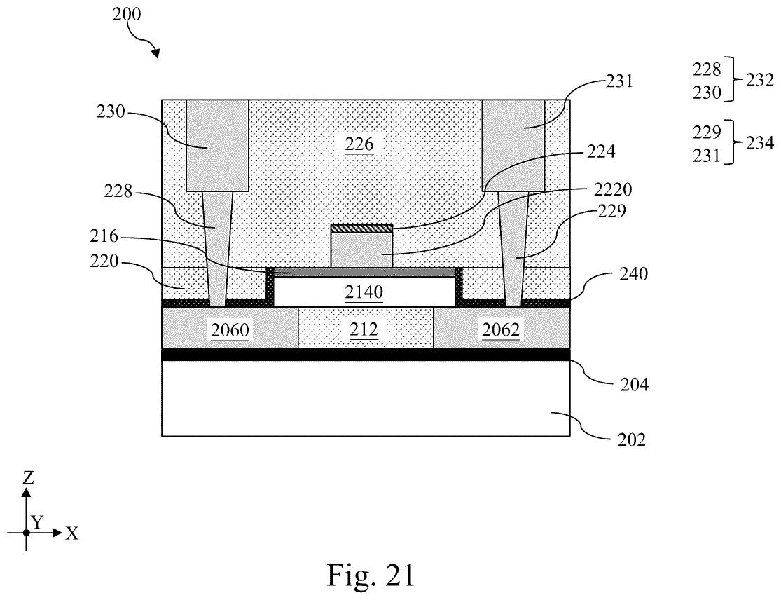

Referring to FIGS. 14 and 21, method 300 includes a block 326 where a first contact structure 232 is formed to couple to the first electrode 2060 and a second contact structure 234 is formed to couple to the second electrode 2062. Operations at block 326 are substantially similar to those at block 124 except that the first via 228 and the second via 229 respectively extend through the spacer layer 240 over the first electrode 2060 and the second electrode 2062. For that reason, detailed description of operations at block 326 is omitted for brevity. As shown in the PCM structure 200 in FIG. 21, the spacer layer 240 spaces the sidewalls of the phase-change element 2140 and the top surfaces of the first electrode 2060 and the second electrode 2062 apart from the second dielectric layer 220. The second dielectric layer 220, which may include silicon oxide, may degrade the phase-change element 2140 and does a poor job in preventing electromigration of the electrodes. The spacer layer 240, which may include silicon nitride, serves to prevent degradation of the phase-change element 2140 and reduce electromigration of the electrodes. It is noted that when the electrodes are formed of metals that are less prone to electromigration, the spacer layer 240 over the electrodes functions more like an etch stop layer when forming the via openings for the first via 228 and the second via 229. To satisfactorily perform its functions, the spacer layer 240 may have a thickness between about 200 Å and about 1000 Å. When the thickness is below 200 Å, the spacer layer 240 is not thick enough to stop oxidation diffusion into the phase-change element 2140. When the thickness is greater than 1000 Å, the spacer layer 240 may cause different etch loading and hinder process integration.

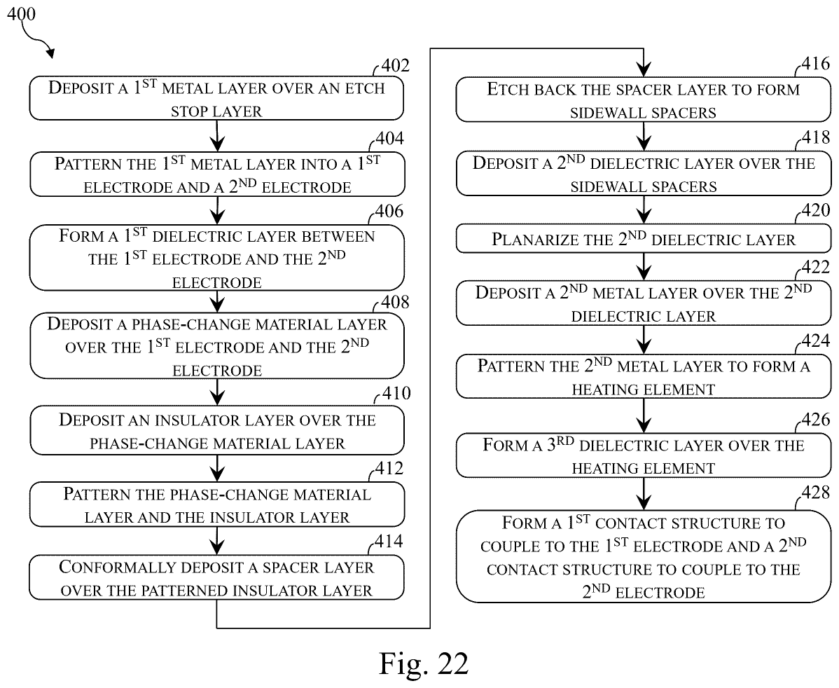

FIG. 22 illustrates a method 400. While method 400 and method 100 share several similar steps, method 400 at least further includes operations to form a spacer layer to isolate sidewalls of the phase-change element 2140 from the second dielectric layer 220.

Referring to FIGS. 22 and 2, method 400 includes a block 402 where a first metal layer 206 is deposited over an etch stop layer (ESL) 204. Operations at block 402 are substantially similar to those at block 102. For that reason, detailed description of operations at block 402 is omitted for brevity.

Referring to FIGS. 22 and 3, method 400 includes a block 404 where the first metal layer 206 is patterned into a first electrode 2060 and a second electrode 2062. Operations at block 404 are substantially similar to those at block 104. For that reason, detailed description of operations at block 404 is omitted for brevity.

Referring to FIGS. 22 and 4, method 400 includes a block 406 where a first dielectric layer 212 is formed between the first electrode 2060 and the second electrode 2062. Operations at block 406 are substantially similar to those at block 106. For that reason, detailed description of operations at block 406 is omitted for brevity.

Referring to FIGS. 22 and 5, method 400 includes a block 408 where a phase-change material layer 214 is deposited over the first electrode 2060 and the second electrode 2062. Operations at block 408 are substantially similar to those at block 108. For that reason, detailed description of operations at block 408 is omitted for brevity.

Referring to FIGS. 22 and 5, method 400 includes a block 410 where an insulator layer 216 is deposited over the phase-change material layer 214. Operations at block 410 are substantially similar to those at block 110. For that reason, detailed description of operations at block 410 is omitted for brevity.

Referring to FIGS. 22 and 6, method 400 includes a block 412 where the phase-change material layer 214 and the insulator layer 216 are patterned. Operations at block 412 are substantially similar to those at block 112. For that reason, detailed description of operations at block 412 is omitted for brevity.

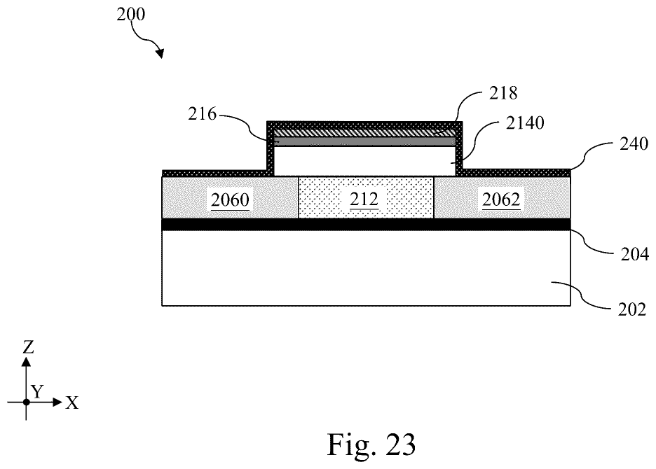

Referring to FIGS. 22 and 23, method 400 includes a block 414 where a spacer layer 240 is conformally deposited over the patterned second mask layer 218 and the patterned insulator layer 216. In some embodiments, the spacer layer 240 may include silicon nitride, silicon oxynitride, or silicon carbide. The spacer layer 240 may be deposited using CVD or a suitable method. As shown in FIG. 23, at block 414, the spacer layer 240 may be deposited along the top surface of the first electrode 2060, sidewalls of the phase-change element 2140, sidewalls of the insulator layer 216, sidewalls of the second mask layer 218, the top surface of the second mask layer 218, and the top surface of the second electrode 2062.

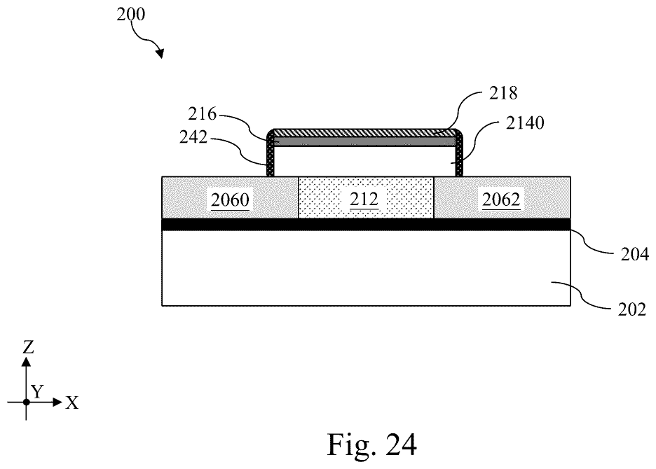

Referring to FIGS. 22 and 24, method 400 includes a block 416 where the spacer layer 240 is etched back to form sidewall spacers 242. The etching back at block 416 may include use of an anisotropic dry etch process to directionally etch away the spacer layer 240 disposed on top-facing surfaces. The anisotropic dry etch process may include use of oxygen-containing gas (e.g., O₂), an inert gas (e.g., Ar) a fluorine-containing gas (e.g., CF₄, C₂F₆, SF₆ or NF₃), other suitable gases and/or plasmas, and/or combinations thereof. As shown in FIG. 24, the etching back at block 416 leaves behind sidewalls spacers 242 extending along sidewalls of the phase-change element 2140 and the insulator layer 216.

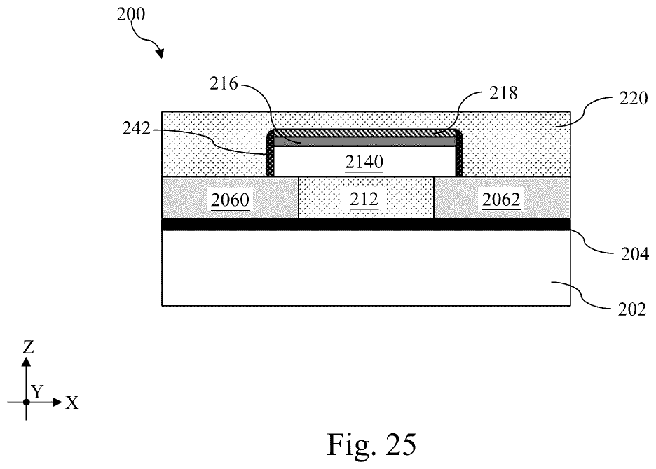

Referring to FIGS. 22 and 25, method 400 includes a block 418 where a second dielectric layer 220 is deposited over the spacer layer 240. Operations at block 418 are substantially similar to those at block 114 except that the second dielectric layer 220 is spaced apart by the sidewall spacers 242 from sidewalls of the phase-change element 2140, the insulator layer 216, and the second mask layer 218 at block 418. For that reason, detailed description of operations at block 418 is omitted for brevity.

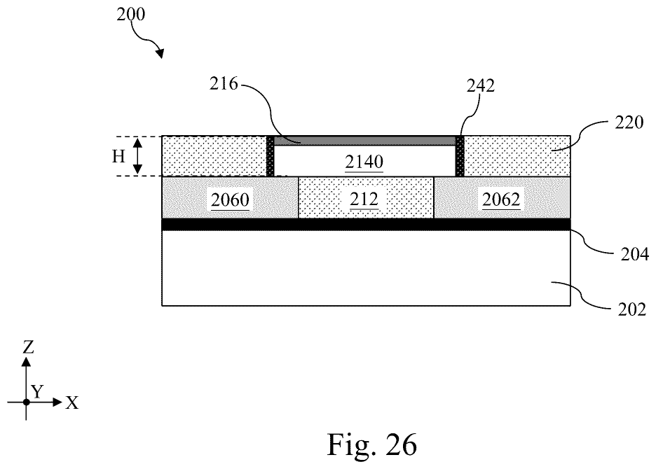

Referring to FIGS. 22 and 26, method 400 includes a block 420 where the second dielectric layer 220 is planarized. Operations at block 420 are substantially similar to those at block 116 except that the planarization at block 420 also planarizes top surfaces of the sidewall spacers 242. For that reason, detailed description of operations at block 420 is omitted for brevity. In some embodiments illustrated in FIG. 26, after the planarization at block 420, the sidewall spacers 242 may have a height H between about 500 Å and about 2500 Å.

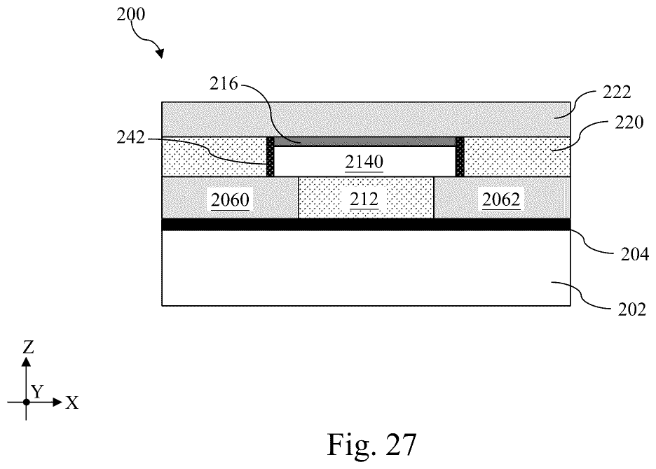

Referring to FIGS. 22 and 27, method 400 includes a block 422 where a second metal layer 222 is deposited over the second dielectric layer 220. Operations at block 422 are substantially similar to those at block 118 except that the second metal layer 222 is also deposited on top surfaces of the sidewall spacers 242. For that reason, detailed description of operations at block 422 is omitted for brevity.

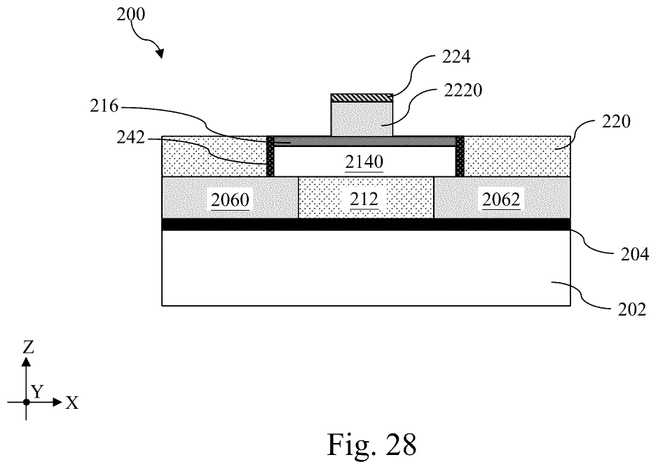

Referring to FIGS. 22 and 28, method 400 includes a block 424 where the second metal layer 222 is patterned to form a heating element 2220. Operations at block 424 are substantially similar to those at block 120. For that reason, detailed description of operations at block 424 is omitted for brevity.

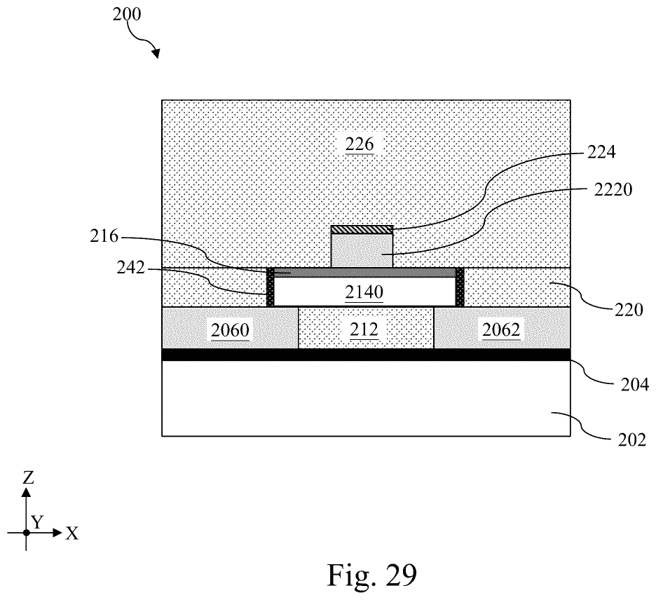

Referring to FIGS. 22 and 29, method 400 includes a block 426 where a third dielectric layer 226 is deposited over heating element 2220. Operations at block 426 are substantially similar to those at block 122 except that the third dielectric layer 226 is also deposited on top surfaces of the sidewall spacers 242. For that reason, detailed description of operations at block 426 is omitted for brevity.

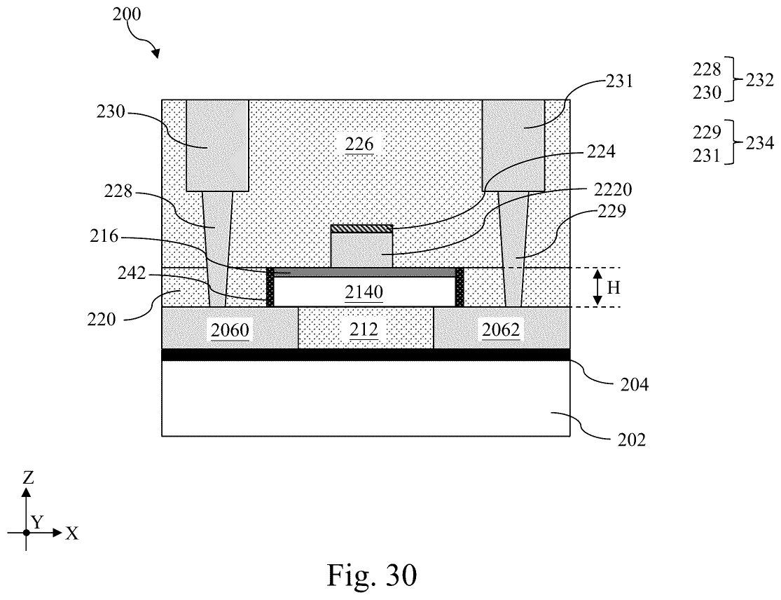

Referring to FIGS. 22 and 30, method 400 includes a block 428 where a first contact structure 232 is formed to couple to the first electrode 2060 and a second contact structure 234 is formed to couple to the second electrode 2062. Operations at block 428 are substantially similar to those at block 124. For that reason, detailed description of operations at block 428 is omitted for brevity. As shown in the PCM structure 200 in FIG. 30, the sidewall spacers 242 space the sidewalls of the phase-change element 2140 apart from the second dielectric layer 220. The second dielectric layer 220, which may include silicon oxide, may degrade the phase-change element 2140. The sidewall spacers 242, which may include silicon nitride, serves to prevent degradation of the phase-change element 2140. It is noted that, in the embodiments represented in FIG. 30, the electrodes are formed of metals that are less prone to electromigration and do not require additional electromigration reduction features, such as the spacer layer 240 in FIG. 21.

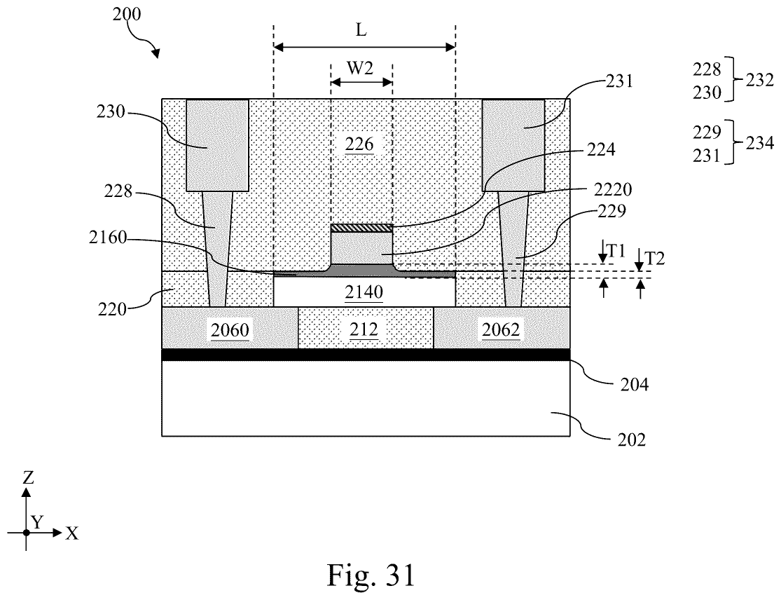

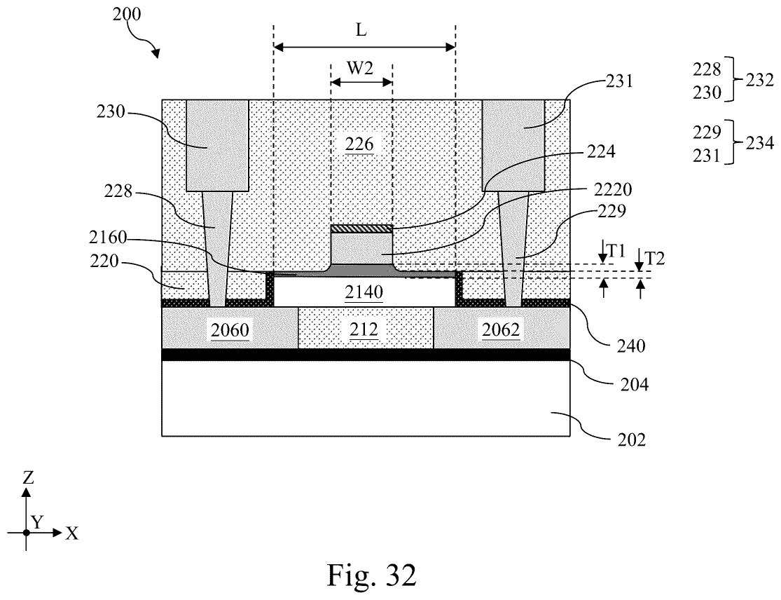

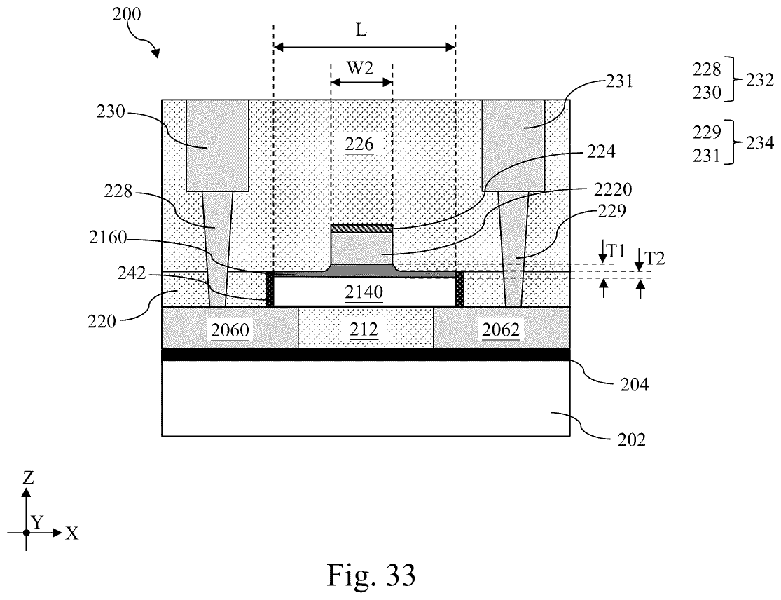

FIGS. 31, 32 and 33 illustrate further embodiments where the insulator layer 216 is partially etched during the patterning of the heating element 2220. As described above in conjunction with FIG. 12, along the X direction, the second conduction width W2 of the heating element 2220 is smaller than the length L of the phase-change element 2140. For that reason, the patterning of the heating element 2220 may also etch portions of the insulator layer 216 that are not covered by the third mask layer 224. As a result, the portion of the insulator layer 216 under the heating element 2220 may have a first thickness T1 and the portion of the insulator layer 216 not covered by the heating element 2220 may have a second thickness T2 smaller than the first thickness T1, as shown in FIGS. 30, 31 and 32. In some instances, the first thickness T1 may be between about 300 Å and about 1500 Å. The second thickness T2 may be between about 50 Å and about 600 Å. The second thickness T2 does not affect the thermal barrier function of the insulator layer 216 as that thinner portion is not under the heating element 2220. In fact, the portion having the smaller second thickness T2 functions more like a protective layer to prevent degradation of the phase-change element 2140. Compared to the embodiment shown in FIG. 11, the embodiment shown in FIG. 31 includes uneven thicknesses for the insulator layer 216, depending on the location. Compared to the embodiment shown in FIG. 31, the embodiment shown in FIG. 32 further includes the spacer layer 240 to space the first electrode 2060, the second electrode 2062 and the sidewalls of the phase-change element 2140 apart from the second dielectric layer 220. Compared to the embodiment shown in FIG. 32, the embodiment shown in FIG. 33 further includes the sidewall spacers 242 to space the sidewalls of the phase-change element 2140 apart from the second dielectric layer 220.

In one exemplary aspect, the present disclosure is directed to a device structure. The device structure includes a first electrode and a second electrode disposed over a substrate, a first dielectric layer disposed between the first electrode and the second electrode, a phase-change material layer disposed over the first electrode, the first dielectric layer and the second electrode, an insulator layer disposed over the phase-change material layer, a metal feature disposed on a top surface of the insulator layer, and a second dielectric layer disposed over the insulator layer, the first electrode, the second electrode, and the metal feature.

In some embodiments, the first electrode and the second electrode include tantalum, titanium, hafnium, ruthenium, platinum, iridium, molybdenum, tungsten, a combination thereof, or a nitride compound thereof. In some embodiments, the metal feature includes tantalum, titanium, hafnium, ruthenium, platinum, iridium, molybdenum, tungsten, a combination thereof, or a nitride compound thereof. In some implementations, the phase-change material layer includes germanium antimony tellurium (GeSbTe), silver indium antimony tellurium (AgInSbTe), or germanium tellurium (GeTe). In some embodiments, the insulator layer includes silicon nitride, silicon oxycarbide, or silicon carbide. In some instances, the first dielectric layer and the second dielectric layer include silicon oxide. In some embodiments, the device structure further includes a mask layer disposed between the metal feature and the second dielectric layer. In some instances, a composition of the mask layer is different from a composition of the second dielectric layer.

In another exemplary aspect, the present disclosure is directed to a structure. The structure includes a first electrode and a second electrode spaced apart from one another along a first direction, a phase-change material layer spanning over and in contact with top surfaces of the first electrode and the second electrode, an insulator layer disposed over the phase-change material layer, and a metal feature disposed on the insulator layer. The metal feature extends lengthwise along a second direction perpendicular to the first direction.

In some embodiments, the metal feature, the first electrode and the second electrode include tantalum, titanium, hafnium, ruthenium, platinum, iridium, molybdenum, tungsten, a combination thereof, or a nitride compound thereof. In some implementations, the phase-change material layer includes germanium antimony tellurium (GeSbTe), silver indium antimony tellurium (AgInSbTe), or germanium tellurium (GeTe). In some instances, the phase-change material layer includes a top surface and bottom surface opposing the top surface, the bottom surface contacts the top surfaces of the first electrode and the second electrode, and the top surface is spaced apart from the metal feature by the insulator layer. In some embodiments, the structure further includes a dielectric layer disposed over the first electrode, the second electrode, the phase-change material, and the metal feature. The structure further includes a first contact structure extending through the dielectric layer to couple to the first electrode, and a second contact structure extending through the dielectric layer to couple to the second electrode. In some embodiments, the structure further includes a third contact structure extending through the dielectric layer to couple to the metal feature at a first contact point and a fourth contact structure extending through the dielectric layer to couple to the metal feature at a second contact point. The first contact point is spaced apart from the second contact point.

In yet another exemplary aspect, the present disclosure is directed to a method. The method includes depositing a first metal layer over an etch stop layer (ESL), patterning the first metal layer into a first electrode and a second electrode, forming a first dielectric layer between the first electrode and the second electrode, forming a phase-change material layer over the first electrode, the first dielectric layer and the second electrode, depositing an insulator layer over the phase-change material layer, patterning the phase-change material layer and the insulator layer such that the phase-change material layer partially overlaps the first electrode and the second electrode, depositing a second dielectric layer over the patterned phase-change material layer and patterned insulator layer, depositing a second metal layer over the second dielectric layer and the patterned insulator layer, patterning the second metal layer to form a heating element that does not vertically overlap the first electrode and the second electrode, and depositing a third dielectric layer over the second dielectric layer and the heating element.

In some embodiments, the first metal layer and the second metal layer include tantalum, titanium, hafnium, ruthenium, platinum, iridium, molybdenum, tungsten, a combination thereof, or a nitride compound thereof. In some implementations, the insulator layer includes silicon nitride, silicon oxycarbide, or silicon carbide. In some instances, the patterning of the second metal layer includes forming a patterned mask layer over the second metal layer, and etching the second metal layer using the patterned mask layer as an etch mask. In some instances, the depositing of the third dielectric layer includes depositing the third dielectric layer over the patterned mask layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
depositing a first metal layer over an interconnect structure;
patterning the first metal layer into a first electrode and a second electrode spaced apart from the first electrode along a first direction;
depositing a first dielectric layer over the first electrode and the second electrode;
planarizing the first dielectric layer to expose the first electrode and the second electrode;
depositing a phase-change material layer over the first electrode, the first dielectric layer and the second electrode;
depositing an insulator layer over the phase-change material layer, the first electrode and the second electrode;
patterning the phase-change material layer and the insulator layer such that the phase-change material layer spans over the first dielectric layer between the first electrode and the second electrode to partially overlap with between the first electrode and the second electrode;
depositing a second dielectric layer over the patterned phase-change material layer and patterned insulator layer;
depositing a second metal layer over the second dielectric layer and the patterned insulator layer; and
patterning the second metal layer to form a heating element that extends lengthwise along a second direction perpendicular to the first direction over the phase-change material layer.

2. The method of claim 1, wherein the phase-change material layer comprises germanium antimony tellurium (GeSbTe), silver indium antimony tellurium (AgInSbTe), or germanium tellurium (GeTe).

3. The method of claim 1, wherein the depositing of the phase-change material layer comprises use of physical vapor deposition (PVD).

4. The method of claim 1, wherein the insulator layer comprises silicon nitride, silicon oxycarbide, or silicon carbide.

5. The method of claim 1,
wherein the first electrode and the second electrode comprises a first width along the second direction,
wherein, after patterning of the phase-change material layer and the insulator layer, the phase-change material layer comprises a second width along the second direction,
wherein the first width is greater than the second width.

6. The method of claim 5,
wherein, after patterning of the phase-change material layer and the insulator layer, the phase-change material layer comprises a length along the first direction,
wherein the heating element comprises a third width along the first direction, and
wherein a ratio of the length to the third width is between about 2 and about 6.

7. The method of claim 5,
wherein the heating element comprises an element length along the second direction,
wherein the element length is greater than the first width.

8. The method of claim 1, wherein the first metal layer and the second metal layer comprise tantalum, titanium, hafnium, ruthenium, platinum, iridium, molybdenum, tungsten, a combination thereof, or a nitride compound thereof.

9. A method, comprising:
depositing a first metal layer over an interconnect structure;
patterning the first metal layer into a first electrode and a second electrode spaced apart from the first electrode along a first direction;
depositing a first dielectric layer over the first electrode and the second electrode;
planarizing the first dielectric layer to expose the first electrode and the second electrode;
depositing a phase-change material layer over the first electrode, the first dielectric layer and the second electrode;
depositing an insulator layer over the phase-change material layer, the first electrode and the second electrode;
patterning the phase-change material layer and the insulator layer such that the phase-change material layer spans over the first dielectric layer between the first electrode and the second electrode to partially overlap with between the first electrode and the second electrode;
depositing a second dielectric layer over the patterned phase-change material layer and patterned insulator layer;
depositing a second metal layer over the second dielectric layer and the patterned insulator layer;
patterning the second metal layer to form a heating element that extends lengthwise along a second direction perpendicular to the first direction over the phase-change material layer;
depositing a third dielectric layer over the heating element, the insulator layer, and the second dielectric layer;
forming a first contact via over the first electrode;
forming a second contact via over the second electrode; and
forming a third contact via and a fourth contact via over the heating element.

10. The method of claim 9,
wherein the first contact via and the second contact via extend through the third dielectric layer and the second dielectric layer, and
wherein the third contact via and the fourth contact via extend through the third dielectric layer.

11. The method of claim 9, wherein the phase-change material layer comprises germanium antimony tellurium (GeSbTe), silver indium antimony tellurium (AgInSbTe), or germanium tellurium (GeTe).

12. The method of claim 9,
wherein, after patterning of the phase-change material layer and the insulator layer, the phase-change material layer comprises a first width along the second direction and a length along the first direction,
wherein a ratio of the length to the first width is between about 2 and about 6.

13. The method of claim 12,
wherein the first electrode and the second electrode comprises a second width along the second direction,
wherein the second width is equal to or greater than the first width.

14. The method of claim 9,
wherein the first electrode and the second electrode comprises a first width along the second direction,
wherein, after patterning of the phase-change material layer and the insulator layer, the phase-change material layer comprises a second width along the second direction, wherein the first width is greater than the second width.

15. The method of claim 14,
wherein, after patterning of the phase-change material layer and the insulator layer, the phase-change material layer comprises a length along the first direction,
wherein the heating element comprises a third width along the first direction, and
wherein a ratio of the length to the third width is between about 2 and about 6.

16. A method, comprising:
depositing a first metal layer over an etch stop layer (ESL),
patterning the first metal layer into a first electrode and a second electrode;
forming a first dielectric layer between the first electrode and the second electrode;
forming a phase-change material layer over the first electrode, the first dielectric layer and the second electrode;
depositing an insulator layer over the phase-change material layer;
patterning the phase-change material layer and the insulator layer such that the phase-change material layer partially overlaps the first electrode and the second electrode;
depositing a second dielectric layer over the patterned phase-change material layer and patterned insulator layer;
depositing a second metal layer over the second dielectric layer and the patterned insulator layer;
patterning the second metal layer to form a heating element that does not vertically overlap the first electrode and the second electrode; and
depositing a third dielectric layer over the second dielectric layer and the heating element.

17. The method of claim 16, wherein the first metal layer and the second metal layer comprise tantalum, titanium, hafnium, ruthenium, platinum, iridium, molybdenum, tungsten, a combination thereof, or a nitride compound thereof.

18. The method of claim 16, wherein the insulator layer comprises silicon nitride, silicon oxycarbide, or silicon carbide.

19. The method of claim 16, wherein the patterning of the second metal layer comprises:
forming a patterned mask layer over the second metal layer; and
etching the second metal layer using the patterned mask layer as an etch mask.

20. The method of claim 19, wherein the depositing of the third dielectric layer comprises depositing the third dielectric layer over the patterned mask layer.
